(19) United States
(12) Patent Application Publication
(10) Pub. No.: US 2013/0313668 A1
(43) Pub. Date: Nov. 28, 2013

(54) PHOTRONIC DEVICE WITH REFLECTOR AND METHOD FOR FORMING

(71) Applicants: Gregory S. Spencer, Pflugerville, TX (US); John R. Alvis, Austin, TX (US); Hsiao-Hui Chen, Austin, TX (US); Joseph F. Orcutt, Austin, TX (US); Srivatsa G. Kundalgurki, Austin, TX (US)

(72) Inventors: Gregory S. Spencer, Pflugerville, TX (US); John R. Alvis, Austin, TX (US); Hsiao-Hui Chen, Austin, TX (US); Joseph F. Orcutt, Austin, TX (US); Srivatsa G. Kundalgurki, Austin, TX (US)

(21) Appl. No.: 13/479,668

(22) Filed: May 24, 2012

(51) Int. Cl. H01L 27/144; H01L 31/18

(52) U.S. Cl. 257/432; 438/59; 257/E27.128; 257/E31.128

(57) ABSTRACT

A photronic device includes a substrate having an opening through the substrate. The photronic device further includes an insulating layer over the substrate including over the opening. The photronic device further includes an active layer over the insulating layer. The photronic device further includes a photoactive device formed in the active layer, wherein the photoactive device is over the opening. The photronic device further includes active electronic circuitry formed in the active layer. The photronic device further includes a reflective layer on the insulating layer in the opening.

### BACKGROUND

1. Field

This disclosure relates generally to photronic devices, and more specifically, to photronic devices with reflectors and methods for forming.

2. Related Art

Photronic devices typically include both photonic devices and electronic devices. Photonic devices may include, for example, passive photonic devices such as wave guides and photoactive devices such as grating couplers and photodetectors. Performance of a photonic device is dependent upon the amount of light which can be captured. Therefore, any loss of light from the photonic devices results in reduced optical efficiency and thus reduced performance.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in cross section form, a photronic device at a stage in processing, in accordance with an embodiment of the present invention.

FIG. 2 illustrates, in cross section form, the photronic device of FIG. 1 at a subsequent stage in processing, in accordance with an embodiment of the present invention.

FIG. 3 illustrates, in cross section form, the photronic device of FIG. 2 at a subsequent stage in processing, in accordance with an embodiment of the present invention.

FIG. 4 illustrates, in cross section form, the photronic device of FIG. 3 at a subsequent stage in processing, in accordance with an embodiment of the present invention.

FIG. 5 illustrates, in cross section form, the photronic device of FIG. 4 at a subsequent stage in processing, in accordance with an embodiment of the present invention.

FIG. 6 illustrates, in cross section form, the photronic device of FIG. 5 at a subsequent stage in processing, in accordance with an embodiment of the present invention.

FIG. 7 illustrates, in cross section form, the photronic device of FIG. 6 at a subsequent stage in processing, in accordance with an embodiment of the present invention.

FIG. 8 illustrates, in cross section form, the photronic device of FIG. 7 at a subsequent stage in processing, in accordance with an embodiment of the present invention.

FIG. 9 illustrates, in cross section form, the photronic device of FIG. 8 or 10 at a subsequent stage in processing, in accordance with an embodiment of the present invention.

FIG. 10 illustrates, in cross section form, the photronic device of FIG. 7 at a subsequent stage in processing, in accordance with an embodiment of the present invention.

### DETAILED DESCRIPTION

Since the performance of many photonic devices is dependent upon the amount of light which can be captured, performance of a photonic device may be improved by improving the efficient of light capture. In one embodiment, one or more photoactive devices are integrated into a silicon-on-insulator (SOI) substrate. A photoactive device may capture light, such as a photodetector, or may redirect light, such as a grating coupler. A wafer back-side reflector is formed under each of the one or more photoactive devices. These wafer back-side reflectors may improve efficiency of light capture or light redirection by reflecting light back into the photoactive devices. In one embodiment, the wafer back-side reflectors are each formed within a cavity formed in the support structure under each of the one or more photoactive devices.

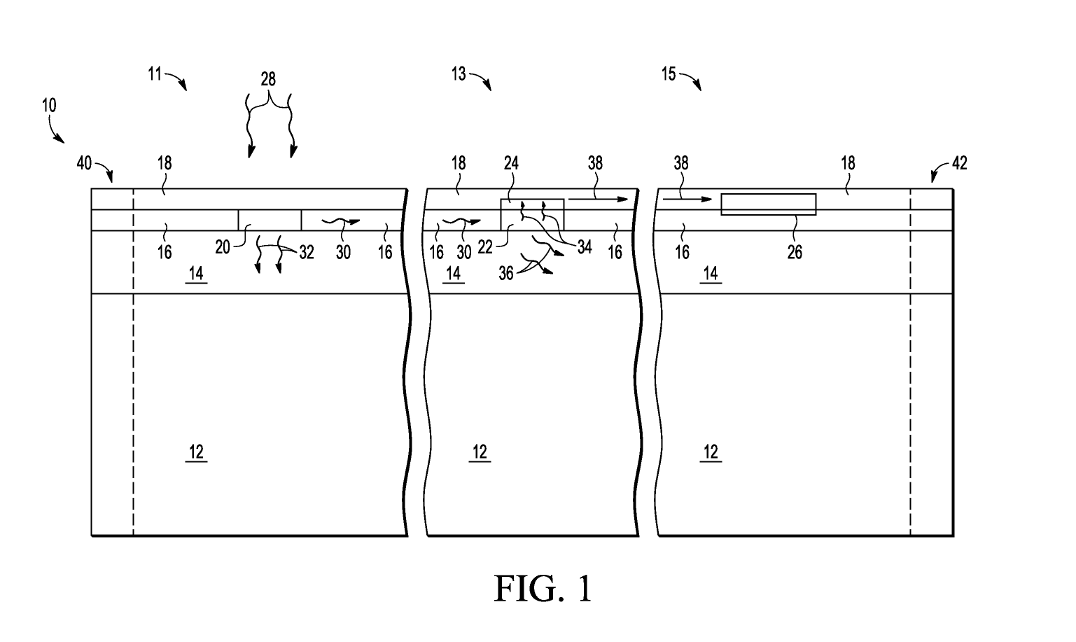

FIG. 1 illustrates, in cross section form, a photronic device 10. In one embodiment, device 10 is a portion of a semiconductor wafer, and includes saw streets 40 and 42. The saw street surrounds the circuitry of device 10 and indicates the regions which will be cut for singulating device 10. Device 10 includes a first region 11, a second region 13, and a third region 15. Photonic devices are formed in regions 11 and 13, and electronic devices are formed in region 15. Device 10 includes a support substrate 12, an insulating layer 14 on substrate 12, a silicon layer 16 on insulating layer 14, and an interconnect layer 18 over insulating layer 14. Silicon layer 16 and insulating layer 14 may correspond to the top silicon layer and insulating layer of an SOI substrate. Support substrate 12 may be a silicon substrate. Silicon layer 16, in region 11, includes a grating coupler 20 formed within silicon layer 16. Silicon layer 16, in region 13, includes a grating coupler 22 formed within silicon layer 16, and a photodetector 24 formed in interconnect layer 18 over grating coupler 22. Region 15 includes active electronic circuitry 26 formed in and on silicon layer 16. Note that grating couplers 20 and 22 and photodetector 24 may all be referred to as photoactive devices. Furthermore, each of these photoactive devices may be replaced with any type of photoactive device, as needed.

Note that silicon layer 16 may also include isolation regions (e.g. shallow trench isolation, deep trench isolation, etc.). Note that interconnect layer 18 may include any number of interconnect layers formed within insulating (i.e. dielectric) layers. Portions of interconnect layer 18 may include only insulating layers without any interconnects. For example, interconnects may not be formed in interconnect layer 18 within region 11, and may only be formed in a portion of interconnect layer 18 within region 13. Note that silicon layer 16 and interconnect layer 18 may be referred to collectively as an active layer. Note also that the active layer may refer to only one of silicon layer 16 and interconnect layer 18. Therefore, a photoactive device or an electronic device which is formed in the active layer may be formed in only silicon layer 16, in only interconnect layer 18, or in both silicon layer 16 and interconnect layer 18.

FIG. 1 also illustrates examples of light and electronic signals within device 10. Incoming light 28 is redirected by grating coupler 20 to travel within the plane of silicon layer 16, towards region 13, as indicated by controlled light 30. That is, controlled light 30 corresponds to the light of incoming light 28 which is controlled by grating coupler 20 by being bent 90 degrees and directed into the wave guide formed by silicon layer 16. However, some of incoming light 28 is not controlled and directed into silicon layer 16 and is instead transmitted through grating coupler 20 into insulating layer 14, as indicated by uncontrolled transmitted light 32. Therefore, uncontrolled transmitted light 32 corresponds to light that is lost in that it does not enter the wave guide in the appropriate direction. Controlled light 30 travels within silicon layer 16 to grating coupler 22 which redirects light into photodetector 24 for capture, as indicated by captured diffracted light 34. The more light of controlled light 30 that grating coupler 22 can redirect into photodetector 24, the better the performance of photodetector 24. However, since grating coupler 22 diffracts light, some light is diffracted away from photodetector 24 and is thus not captured by photodetector 24, as indicated by uncaptured diffracted light 36. Therefore, uncaptured diffracted light 36 corresponds to light that is lost in that it does not get captured by photodetector 24.

Photodetector 24 converts captured diffracted light 34 into electrical signals, as represented by electrical signals 38, which can be transmitted by interconnect layer 18 to electronic circuitry 26 in region 15. Lost light 32 and 36 may result in reduced performance of photronic device 10 since this lost light is not captured by photodetector 24 and thus not converted to electrical signals. As will be described in more detail below, cavities will be formed under each photoactive device (e.g. grating coupler 20 and grating coupler 22/photodetector 24) in support substrate 12 so that a reflective layer may be formed within the cavities and in contact with insulating layer 14 under the photoactive devices. Note that in the descriptions herein, the top side of device 10 refers to the side having interconnect layer 18 and silicon layer 16. That is, the photronic circuitry of device 10 is located at the top side of the wafer. In the descriptions herein, the back side of device 10 refers to the side having the support substrate 12, and is opposite the top side of device 10. Therefore, in FIG. 1, the top side may refer to the exposed surface of interconnect layer 18 and the bottom side may refer to the exposed surface of substrate 12.

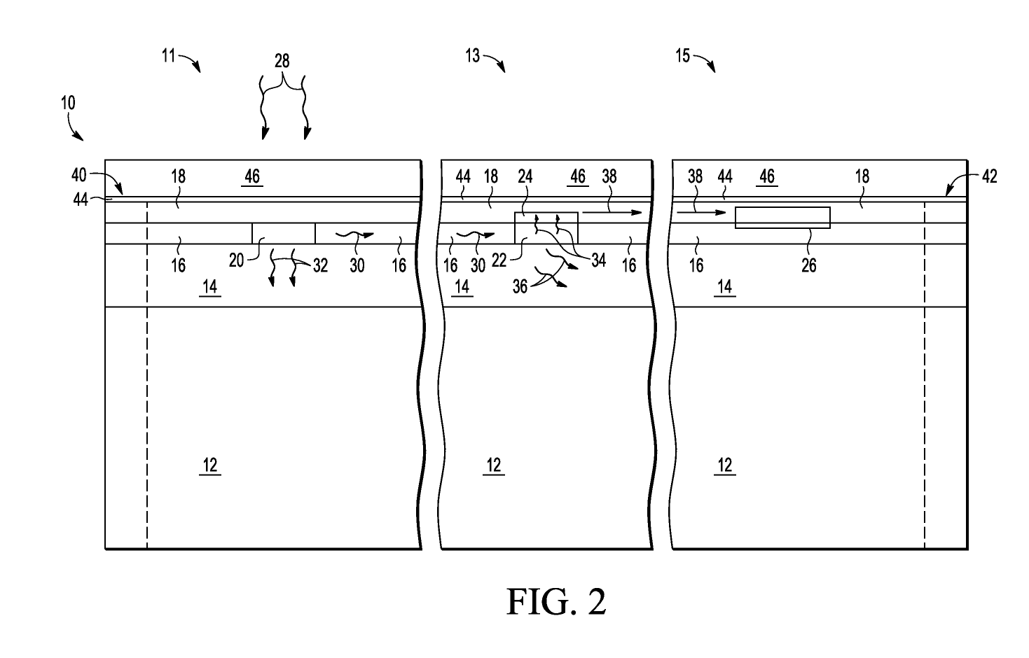

FIG. 2 illustrates, in cross section form, photronic device 10 at a subsequent stage in processing. A protection layer 44 is formed over interconnect layer 18 (on the top side of device 10) and protects the top-side metal of interconnect layer 18. In one embodiment, protection layer 44 is a blanket deposited titanium nitride layer. A protection layer 46 is formed over protection layer 44 (on the top side of device 10). In one embodiment, protection layer 46 is a blanket deposited phosphorous doped silicon glass (PSG), tetraethylorthosilicate (TEOS) oxide, or oxynitride.

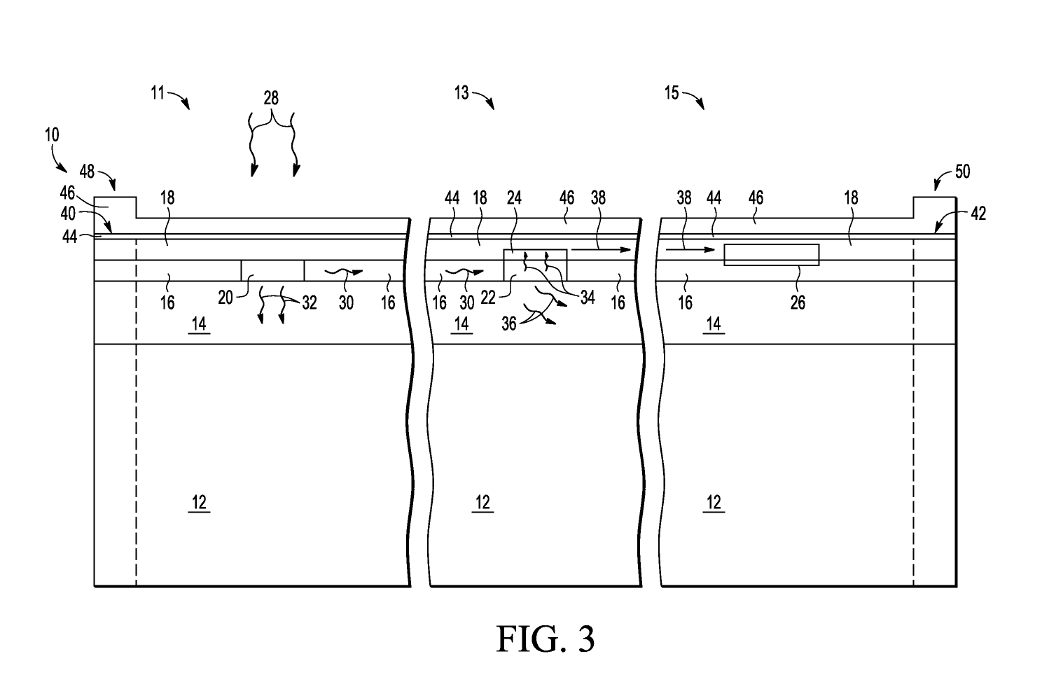

FIG. 3 illustrates, in cross section form, photronic device 10 at a subsequent stage in processing. Protection layer 46 is patterned so as to remove a top portion of protection layer 46 within the region defined by the saw street. In this manner, standoff portions 48 and 50 of protection layer 46 remain over the saw streets. Therefore, standoff portions 48 and 50 of protection layer 46 are thicker as compared to the remaining portions of protection layer 46 within the region defined by the saw street, such as over photoactive devices 20, 22, and 24 and electronic devices 26.

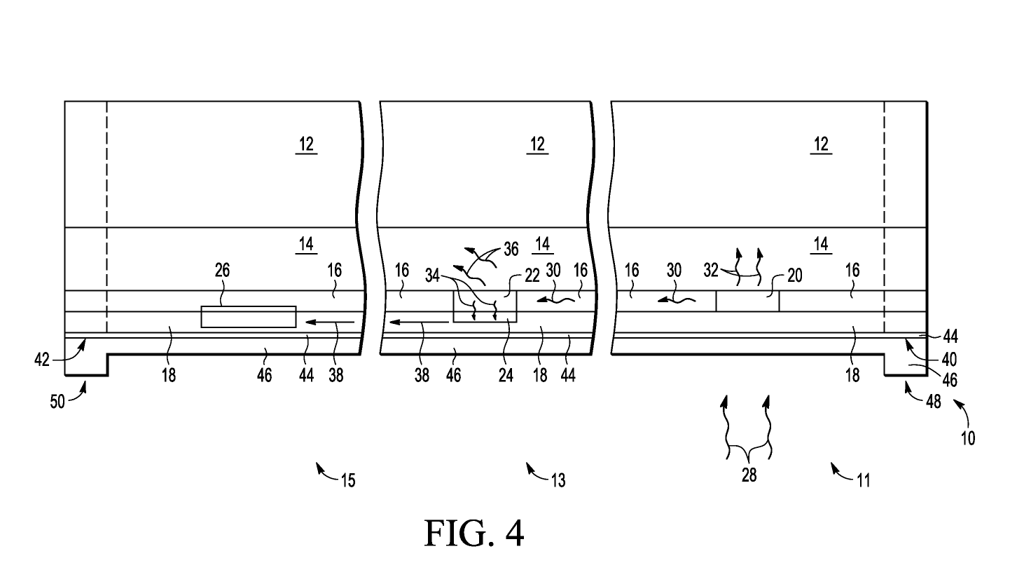

FIG. 4 illustrates, in cross section form, photronic device 10 at a subsequent stage in processing. In FIG. 4, device 10 is flipped over and placed on its top side in order to expose the backside of device 10. Note that protection layer 46 provides protection to the photronic circuitry of device 10 while performing backside processing. Furthermore, note that standoffs 50 and 48 support device 10 while the thinner portions of protection layer 46, between standoffs 50 and 48, protect the topography of the photronic surface at the top side of device 10. Note that the standoffs have a thickness sufficient to protect the topography of the top side.

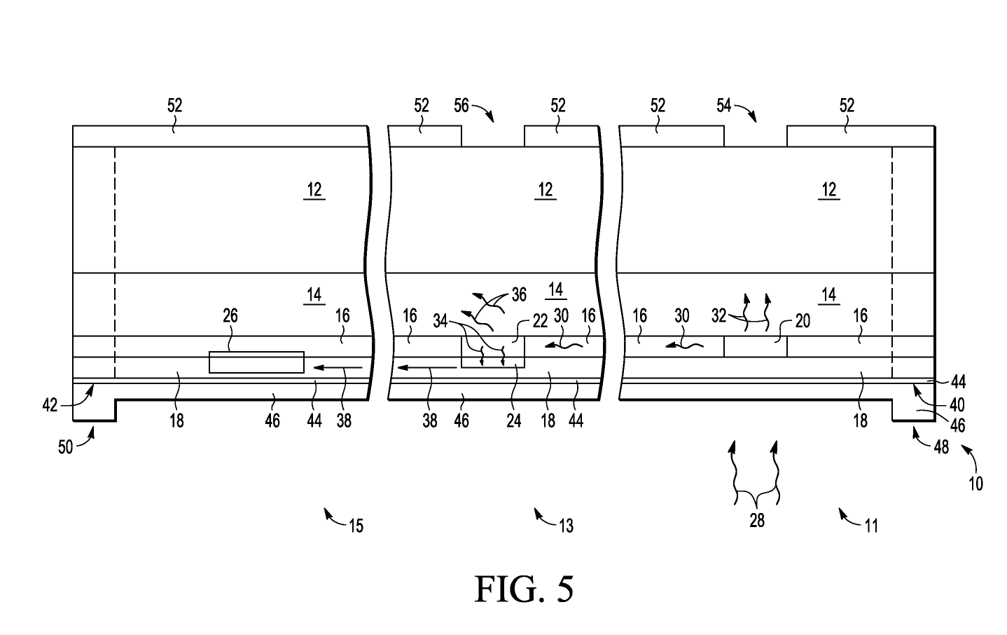

FIG. 5 illustrates, in cross section form, photronic device 10 at a subsequent stage in processing. In one embodiment, support substrate 12 is thinned. In one embodiment, about half the thickness of support substrate 12 is removed. A patterned hard mask layer 52 is then formed over support substrate 12. Note that in alternate embodiments, support substrate 12 may not be thinned prior to formation of patterned hard mask layer 52. Patterned hard mask layer 52 includes an opening 54 which corresponds to grating coupler 20 and an opening 56 which corresponds to grating coupler 22 and photodetector 24. That is, opening 54 is aligned to a corresponding photoactive device (grating coupler 20) and opening 56 is aligned to a corresponding photoactive device (grating coupler 22 and photodetector 24).

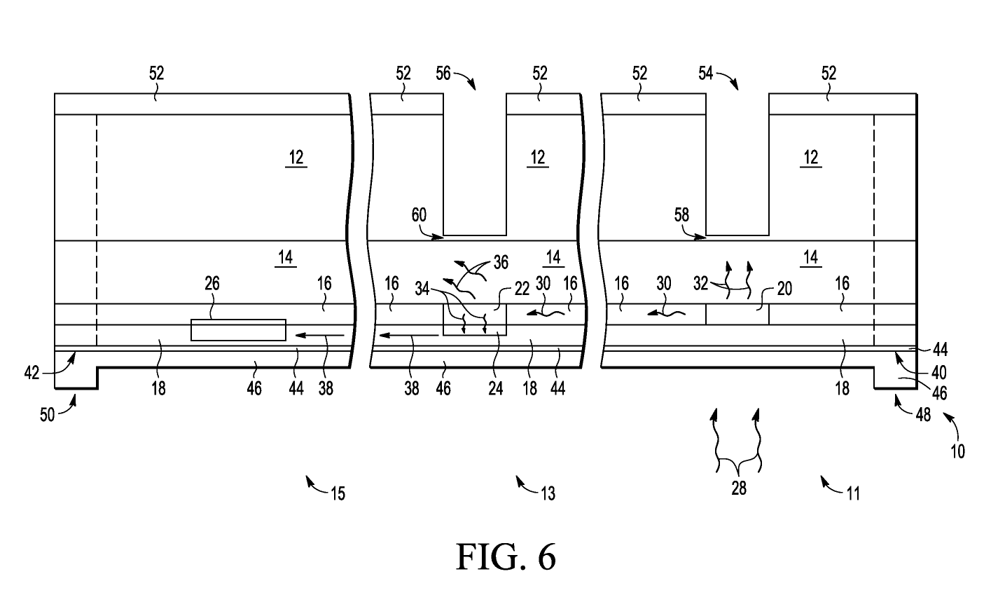

FIG. 6 illustrates, in cross section form, photronic device 10 at a subsequent stage in processing. An etch is performed into substrate 12 to a first depth with a first etchant applied through openings 54 and 56 of patterned hard mask 52. In this manner openings 56 and 54 are extended into substrate 12 to the first depth to form openings above photoactive devices 22 and 20, respectively. In the illustrated embodiment, openings 56 and 54 do not fully extend through substrate 12 to insulating layer 14. That is, remaining portions 60 and 58 of substrate 12 remain at the bottom of each of openings 56 and 54, respectively. In one embodiment, the thickness of remaining portions 60 and 58 is in a range of about 5 to 25 microns.

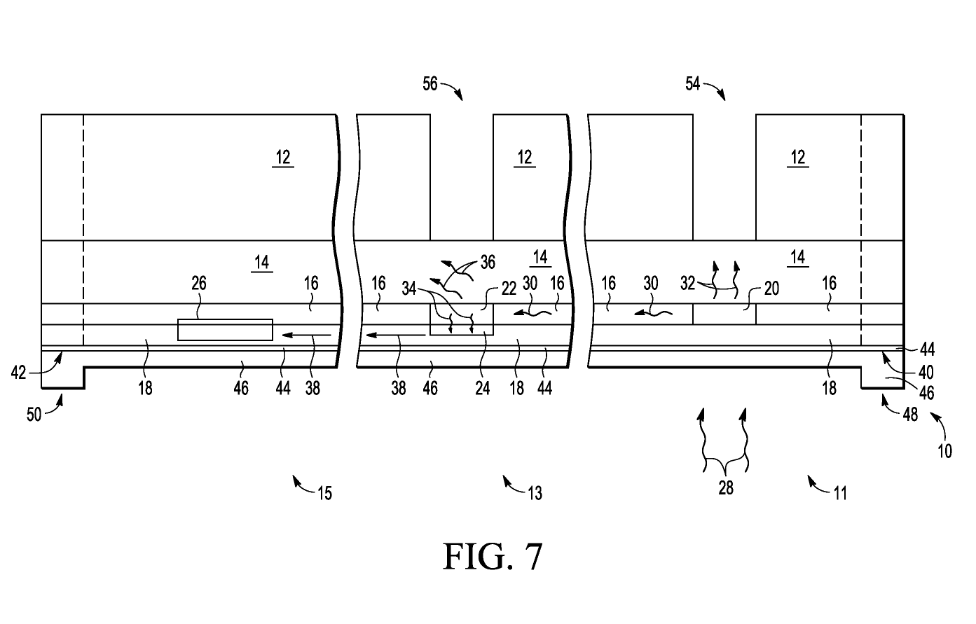

FIG. 7 illustrates, in cross section form, photronic device 10 at a subsequent stage in processing. In one embodiment, patterned hard mask layer 52 is removed. After removal of patterned hard mask layer 52, an etch is performed using a second etchant, different from the first etchant, to extend openings 54 and 56 to insulating layer 14, so as to expose insulating layer 14 in each of the openings. In one embodiment, this etch is performed using a silicon etchant that is selective to oxide as the second etchant, such as, for example, tetramethylammonium hydroxide (TMAH) or potassium hydroxide (KOH). In this embodiment, substrate 12 is a silicon substrate and TMAH or KOH is a silicon etchant that is selective to oxide. The use of a silicon etchant which is selective to oxide allows for a more controlled etch such that openings 56 and 54 may be extended through remaining portions 58 and 60 of substrate 12 to expose insulating layer 14 but without etching away any significant portions of insulating layer 14. In this manner, the full thickness of insulating layer 14, which may be critical depending on the application, may remain.

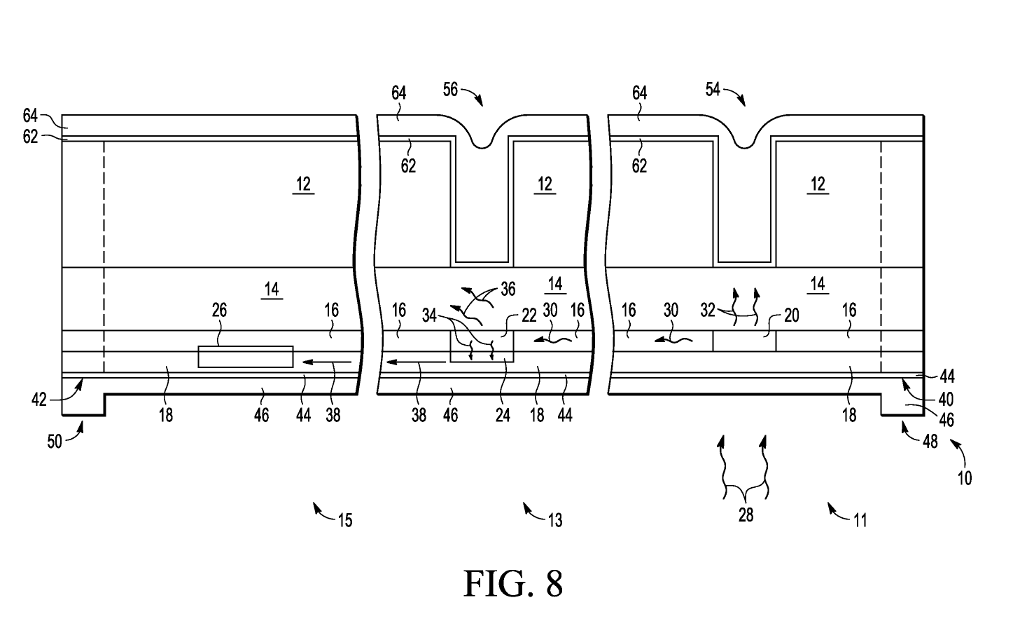

In an alternate embodiment, such as in an application in which the thickness of insulating layer 14 is not as critical or can be thinned, the etch described above in reference to FIG. 6 using patterned hard mask layer 52 may be performed such that openings 56 and 54 are formed to extend into insulating layer 14. In this embodiment, patterned hard mask layer 52 is not removed, and openings 56 and 54 are fully etched in the same etch step using the same etchant, without needing the second etchant of FIG. 7. Therefore, note that if this alternate embodiment is performed, patterned masking layer 52 would still be present in FIGS. 8-10.

Note that each of the openings formed in substrate 12, such as openings 56 and 54, are aligned to a corresponding photoactive device. Furthermore, an area of each opening may be substantially the same as the area of the corresponding photoactive device. For example, opening 56 is aligned to grating coupler 22 and photodetector 24 and may have an area that is substantially the same as the area of grating coupler 22, and opening 54 is aligned to grating coupler 20 and may have an area that is substantially the same as the area of grating coupler 20. The openings in substrate 12 (such as openings 56 and 54) which are aligned to a corresponding photoactive device may be of any shape, and in one embodiment, have a width of at least 30 microns. Alternatively, they may have a width of at least 70 microns or at least 100 microns or at least 130 microns. In one embodiment, in which the openings are circular openings, the width corresponds to the opening's diameter.

In another embodiment, openings 56 and 54 formed in substrate 12 and aligned to photoactive devices 20, 22, and 24 may be larger than the photoactive active devices. In this embodiment, the effects of the cavity (i.e. opening) edges on the subsequent reflector (i.e. reflective layer) formation are reduced. For example, opening 56 is aligned to grating coupler 22 and photodetector 24 and may have an area that is 30 microns larger than the area of grating coupler 22, and opening 54 is aligned to grating coupler 20 and may have an area that is 30 microns larger than the area of grating coupler 20.

FIG. 8 illustrates, in cross section form, photronic device 10 at a subsequent stage in processing. A reflective layer 62 is formed over substrate 12 and within openings 56 and 54. In one embodiment, reflective layer 62 is a conformal layer which may be formed by plasma vapor deposition (PVD), an evaporative deposition process, or atomic layer deposition (ALD). Alternatively, a solder jet method may be used. As will be described in more detail below, reflect layer 62 is formed at the bottom of openings 56 and 54 such that it is in direct physical contact with insulating layer 14 over photoactive devices 22 and 20, such that reflective layer 62 covers each of devices 22 and 20. Therefore, in one embodiment, each portion of reflective layer 62 which is formed within an opening of substrate 12 that is in contact with insulating layer 14 has an area that is substantially the same as the area of the corresponding photoactive device. Also, note that an interface between insulating layer 14 and substrate 12 is coplanar with an interface between reflective layer 62 (in each of openings 54 and 56) and insulating layer 14.

In one embodiment, reflective layer 62 is a metal layer, which includes, for example, aluminum, silver, gold, platinum, titanium, tin, or nickel, or combinations thereof. The particular material selected and material thickness formed for reflective layer 62 is based upon the wavelength of the light being transmitted as well as the transmission and absorption properties of the material. For example, in one embodiment, the wavelength of incoming light 28 is infrared and has, for example, a wavelength in a range of 1260 to 1650 nanometers. In this example, reflective layer 62 may be an aluminum and copper layer with a thickness of greater than 35 nanometers (nm). A protection layer 64 is formed over reflective layer 62. In one embodiment, protection layer 64 is formed using a spin-on or spray-on process. In this example, protection layer 64 may be photoresist, a polyimide, an organic material, or glass. In one embodiment, protection layer 64 may be an oxynitride performed by plasma enhanced chemical vapor deposition (PECVD). In one embodiment, protection layer 64 covers all of reflective layer 62.

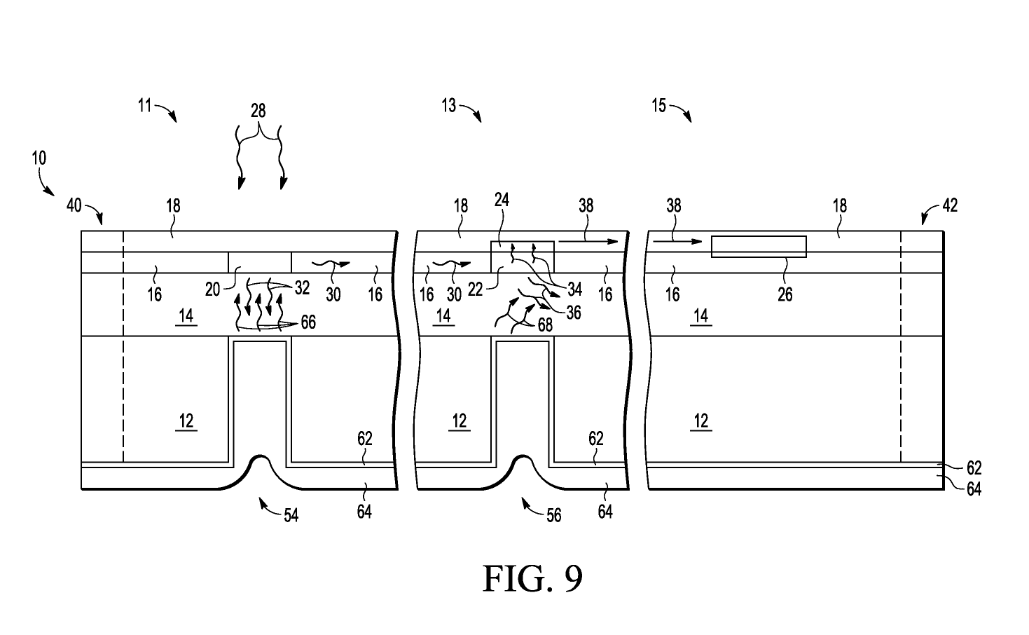

FIG. 9 illustrates, in cross section form, photronic device 10 at a subsequent stage in processing. In FIG. 9, device 10 is again flipped onto its backside so as to again expose the top side. Once the top side is exposed, protection layers 44 and 46 are removed. Note that with reflective layer 62 located within openings 54 and 56 under insulating layer 14 and under photoactive devices 20 and 22, lost light can be reflected back to the photoactive devices in order to improve optical efficiency. For example, reflective layer 62 in opening 54 can reflect some or all of uncontrolled transmitted light 32 back to grating coupler 20, as indicated by reflected light 66. Similarly, reflective layer 62 in opening 56 can reflect some or all of uncaptured diffracted light 36 back to grating coupler 22 and thus photodetector 24, as indicated by reflected light 68.

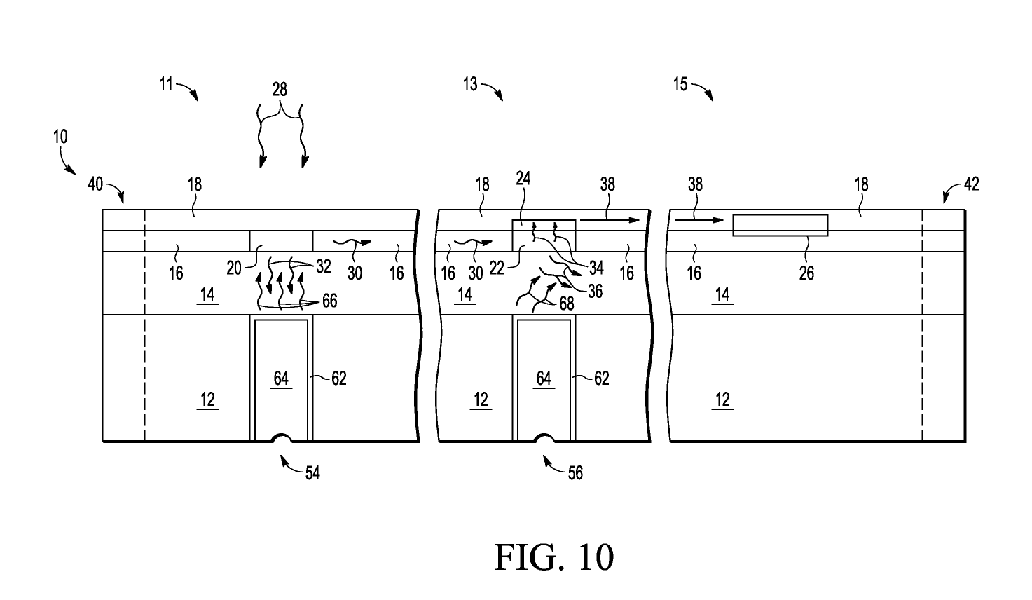

In one embodiment, additional processing may be performed on photronic device 10 after FIG. 8 and prior to FIG. 9. This additional processing is illustrated in FIG. 10. In FIG. 10, a polish or lift off may be performed on photronic device 10 to remove portions of reflective layer 62 and protection layer 64 which are not within openings 54 and 56. In this manner, substrate 12 is exposed. In one embodiment, after the polish or lift off, remaining portions of protection layer 64 covers all remaining portions of reflective layer 62. Note that in alternate embodiments, this polish or lift off is not performed, in which case, the process proceeds from the processing stage illustrated in FIG. 8 to the processing stage illustrated in FIG. 9, without the polish or lift off.

By now it should be understood how optical efficiency may be improved through the use of a reflective layer within openings formed under photonic devices. In one embodiment, a photronic device (e.g. device 10) includes a substrate (e.g. substrate 12), an insulating layer (e.g. insulating layer 14) over the substrate, and an active layer (e.g. one or both of layers 16 and 18) over the insulating layer. The photronic device includes both photoactive devices (e.g. devices 20, 22, and 24) and active electronic circuitry (e.g. circuitry 26) formed in the active layer. The substrate includes an opening (e.g. openings 54 and 56) corresponding to each photoactive device, in which each photoactive device is over a corresponding opening. Within each opening, a reflective layer (e.g. reflective layer 62) is formed on the insulating layer. In this manner, each photoactive device is formed over a corresponding opening, in which the insulating layer is between the photonic device and opening, and a reflective material is formed on the insulating layer within the openings in order to reflect any previously uncontrolled or uncaptured light back to the corresponding photonic device.

In alternate embodiments, other types of photoactive devices may be used. For example, a reflective layer may be formed under a grating coupler which provides light external to the device rather than receives light as grating couplers 20 and 22 do. Also, a reflective layer may be formed under a photodetector in which no grating coupler is provided under the photodetector. In this embodiment, the photodetector may be formed in interconnect layers 18 and may extend down into silicon layer 16. The light is received vertically (i.e. the incoming light to the photodetector is received from the top surface of the device in which light is provided in a direction perpendicular to the top surface of the device), and any light which is transmitted through the photodetector which would otherwise be lost can be reflected by the reflective layer back to the photodetector. In this manner, optical efficiency may be improved.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, a reflective layer such as reflective layer 62 may be used for various different configurations and types of photoactive devices. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention.

Item 1 includes a photronic device, including a substrate having an opening through the substrate; an insulating layer over the substrate including over the opening; an active layer over the insulating layer; a photoactive device formed in the active layer, wherein the photoactive device is over the opening; active electronic circuitry formed in the active layer; and a reflective layer on the insulating layer in the opening. Item 2 includes the photronic device of item 1, wherein the reflective layer comprises a metal layer. Item 3 includes the photronic device of item 2, wherein the photoactive device has a first area, the opening has a second area, and the first area is substantially equal to the second area. Item 4 includes the photronic device of item 3, wherein the photoactive device is substantially aligned to the opening. Item 5 includes the photronic device of item 3, wherein the reflective layer includes one of a group consisting of aluminum, silver, gold, platinum, titanium, tin, and nickel. Item 6 includes the photronic device of item 1, wherein the active layer includes a silicon layer. Item 7 includes the photronic device of item 6, wherein the photoactive device comprises a rating coupler. Item 8 includes the photronic device of item 1, wherein the active layer includes a silicon layer on the insulating layer; and an interconnect layer over the silicon layer. Item 9 includes the photronic device of item 8, wherein the photoactive device comprises a photodetector. Item 10 includes the photronic device of item 1, wherein an interface between the insulating layer and the substrate is coplanar with an interface between the reflective layer and the insulating layer, further including a protective layer covering all of the reflective layer.

Item 11 includes a method of making a photronic device using a substrate, an insulating layer over the substrate, and an active layer over the insulating layer, the method including forming an opening through the substrate to the insulating layer; forming a reflective layer on the insulating layer in the opening; forming a photoactive device in the active layer over the opening; and forming active electronic circuitry in the active layer. Item 12 includes the method of item 11, and further includes aligning the photoactive device to the opening. Item 13 includes the method of item 12, wherein the forming the reflective layer is further characterized by the reflective layer includes one of a group consisting of aluminum, silver, gold, platinum, titanium, tin, and nickel. Item 14 includes the method of item 13, wherein the active layer includes a silicon layer and the forming the photoactive device includes forming a grating coupler. Item 15 includes the method of item 11, wherein the active layer includes a silicon layer on the insulating layer and an interconnect layer over the silicon layer and the forming the photoactive device includes forming a photodetector. Item 16 includes the method of item 11, and further includes forming a protective layer covering all of the reflective layer. Item 17 includes the method of item 11, wherein the forming the opening in the insulating layer includes forming a hard mask on the substrate; forming an opening in the hard mask; etching the substrate using a first etchant applied through the opening in the hard mask to etch the substrate to a first depth and then switching to a second etchant to finish etching to the insulating layer, wherein the second etchant includes a silicon etchant that is selective to oxide. Item 18 includes the method of item 11, and further includes forming a second opening through the substrate to the insulating layer; and forming a second reflective layer on the insulating layer in the second opening; and forming a second photoactive device in the active layer over the second opening.

Item 19 includes a photronic device, including a silicon substrate having a first opening through the substrate and a second opening through the substrate; an insulating layer over the substrate including over the first opening and the second opening; an active layer having a silicon layer over the insulating layer and an interconnect layer over the silicon layer; a grating coupler in the active layer and over the first opening; a photodetector in the active layer and over the second opening; active electronic circuitry formed in the active layer; a first reflective layer on the insulating layer in the first opening; and a second reflective layer on the insulating layer in the second opening. Item 20 includes the photronic device of item 19, wherein the grating coupler is aligned to the first opening; and the photodetector is aligned to the second opening; and further including a first protective layer on the first reflective layer; and a second protective layer on the second reflective layer.

What is claimed is:

1. A photronic device, comprising:
a substrate having an opening through the substrate;
an insulating layer over the substrate including over the opening;
an active layer over the insulating layer;
a photoactive device formed in the active layer, wherein the photoactive device is over the opening;
active electronic circuitry formed in the active layer; and
a reflective layer on the insulating layer in the opening.

2. The photronic device of claim 1, wherein the reflective layer comprises a metal layer.

3. The photronic device of claim 2, wherein the photoactive device has a first area, the opening has a second area, and the first area is substantially equal to the second area.

4. The photonic device of claim 3, wherein the photoactive device is substantially aligned to the opening.

5. The photronic device of claim 3, wherein the reflective layer comprises one of a group consisting of aluminum, silver, gold, platinum, titanium, tin, and nickel.

6. The photronic device of claim 1, wherein the active layer comprises:
a silicon layer.

7. The photronic device of claim 6, wherein the photoactive device comprises a grating coupler.

8. The photronic device of claim 1, wherein the active layer comprises:
a silicon layer on the insulating layer; and
an interconnect layer over the silicon layer.

9. The photronic device of claim 8, wherein the photoactive device comprises a photodetector.

10. The photronic device of claim 1, wherein an interface between the insulating layer and the substrate is coplanar with an interface between the reflective layer and the insulating layer, further comprising a protective layer covering all of the reflective layer.

11. A method of making a photronic device using a substrate, an insulating layer over the substrate, and an active layer over the insulating layer, comprising:
forming an opening through the substrate to the insulating layer;
forming a reflective layer on the insulating layer in the opening;
forming a photoactive device in the active layer over the opening; and
forming active electronic circuitry in the active layer.

12. The method of claim 11, further comprising aligning the photoactive device to the opening.

13. The method of claim 12, wherein the forming the reflective layer is further characterized by the reflective layer comprises one of a group consisting of aluminum, silver, gold, platinum, titanium, tin, and nickel.

14. The method of claim 13, wherein the active layer comprises a silicon layer and the forming the photoactive device comprises forming a grating coupler.

15. The method of claim 11, wherein the active layer comprises a silicon layer on the insulating layer and an interconnect layer over the silicon layer and the forming the photoactive device comprises forming a photodetector.

16. The method of claim 11, further comprising forming a protective layer covering all of the reflective layer.

17. The method of claim 11, wherein the forming the opening in the insulating layer comprises:
forming a hard mask on the substrate;
forming an opening in the hard mask;
etching the substrate using a first etchant applied through the opening in the hard mask to etch the substrate to a first depth and then switching to a second etchant to finish etching to the insulating layer, wherein the second etchant comprises a silicon etchant that is selective to oxide.

18. The method of claim 11, further comprising:
forming a second opening through the substrate to the insulating layer; and
forming a second reflective layer on the insulating layer in the second opening; and
forming a second photoactive device in the active layer over the second opening.

19. A photronic device, comprising:
a silicon substrate having a first opening through the substrate and a second opening through the substrate;
an insulating layer over the substrate including over the first opening and the second opening;
an active layer having a silicon layer over the insulating layer and an interconnect layer over the silicon layer;
a grating coupler in the active layer and over the first opening;
a photodetector in the active layer and over the second opening;
active electronic circuitry formed in the active layer;
a first reflective layer on the insulating layer in the first opening; and
a second reflective layer on the insulating layer in the second opening.

20. The photronic device of claim 19, wherein:
the grating coupler is aligned to the first opening; and
the photodetector is aligned to the second opening;
further comprising:
a first protective layer on the first reflective layer; and
a second protective layer on the second reflective layer.
